(19) United States
(12) Patent Application Publication
(10) Pub. No.: US 2012/0242514 A1
(43) Pub. Date: Sep. 27, 2012

(54) HYBRID KEYBOARD

(75) Inventor: Min-Chih HSUAN, Hsinchu City (TW)

(73) Assignee: Smile Technology Co., Ltd., Mahe' (SC)

(21) Appl. No.: 13/070,835

(22) Filed: Mar. 24, 2011

(51) Int. Cl. H03K 17/94

(52) U.S. Cl. 341/22

(57) ABSTRACT

The invented hybrid keyboard comprises: a main body, to provide an enclosing space; an input key assembly including at least one input key and a corresponding encoder, to generate predetermined signals in response to striking operations of said at least one input key; and an output module, to pick up said signals generated by said input key assembly and to output said signals; characterized in that said input key assembly further comprises a motion sensor, to generate predetermined signals in response to motions detected by said motion sensor.

### FIELD OF THE INVENTION

The present invention relates to a hybrid keyboard, especially to a hybrid keyboard that uses two or more types of the input key.

### BACKGROUND OF THE INVENTION

Using the keyboard to input control signals to all kinds of computer, communication and household appliances has become a part of our daily life. A variety of the keyboard system has been developed in accordance with the different needs in the application and in the control of these computer, communication and household appliances.

The traditional keyboard has at least the following major modules: One is the keyboard module, which comprises one or more input keys. Each input key, in responding to the pressing operation of the user, generates as encoded signal representing a predetermined code. The other module is the transmission module that transmits the codes or other signals generated by the input keys to a host machine, to operate or to control the host machine. The transmission module may be a wired communication module that connects the communication interfaces of the host machine through a cable, a flat cable, a signal line etc. It may be a wireless transmission module that connects the wireless communication interfaces of the host machine or a receiver in connection with the communication interfaces of the host machine, through the infra red, the wireless, the microwave or other transmission channels. These keyboard devices and communication methods are well known to those skilled in the art.

In the conventional keyboard systems, however, all the control signals are generated by the input keys. As a result, in order to increase the quantity of the control functions, the number of the input keys shall also increases. This in turn would make the area of the control panel enlarged, or on the other hand reduce the area of the input keys. The possible result of such request would either be a bulky and costly control device or smaller input keys not easy to operate or use. More preferable solutions to these technical problems are needed.

On possible solution to reduce the number of the input keys is to use the multiple-leveled input key encoding technology. For example, if all the input keys are organized to groups of 4 keys, the number of the input keys for a keyboard may be reduced to ¼. In other words, to provide totally 4n kinds of control function only n input keys would be needed if each set of 4 functions is controlled by one input key and each signal is generated by striking the input keys for twice. In doing so, the n must be equal to or greater than 4 and the user may need to strike two times to generate one signal. Depending on the combinations in the input keys, the users are further required to understand or to memorize the key combinations, so that correct control signals may be input. Nevertheless, the users must memorize the positions of the input keys and strike them in predetermined orders, whereby correct control signals may be generated. For ordinary users such keyboard is difficult to use. If the level of the input key combination is more than 2 (2 keystrokes are required in generating one code), the users would experience more difficult in using the multiple level keyboard.

In addition, even if the input keys are not in a large number, to allocate the proper keys to generate correct signals is a difficult task for the users. In some systems, the “transmit’ and “send” signals are also generated by pushing a corresponding input key. If the user did not push the “transmit” or “send” key within the limited time, the key stokes made previously and stored would be canceled. Therefore, all the sequential key strokes must be repeated. Even if the “transmit” or “send” key is made large and easy to find, to strike the “transmit” or “send” key to send the series of key strokes stored temporarily is not a convenient way of using the keyboard.

Therefore, it is necessary to provide a novel keyboard system that allows the users to operate the input keys by the combination of operations in different manners. It is also necessary to provide a hybrid keyboard to receive the operations of the users in different manners, therefore to reduce the number of the needed input keys. It is also necessary to provide a hybrid keyboard that may be operated by the combination of different operation manners therefore is easy to operate.

### OBJECTIVES OF THE INVENTION

An objective of this invention is to provide a novel keyboard system that allows the users to operate the input keys by the combination of operations in different manners.

Another objective of this invention is to provide a hybrid keyboard to receive the operations of the users in different manners, therefore to reduce the number of the needed input keys.

Another objective of this invention is to provide a hybrid keyboard that may be operated by the combination of different operation manners therefore is easy to operate.

### SUMMARY OF THE INVENTION

The hybrid keyboard of this invention comprises a main body, to provide an enclosing space; an input key assembly including at least one input key and corresponding encoder, to generate predetermined signals in response to striking operations of said at least one input key; and an output module, to pick up said signals of said input key assembly and to output said signals; characterized in that said input key assembly further comprises a motion sensor, to generate predetermined signals in response to motions detected by said motion sensor.

In one embodiment of this invention, the input key assembly may have only one input key, while in other embodiments, the input key assembly has a plurality of input keys. In the preferred embodiments, the plurality of the input keys includes the numeric keys from 0-9. In some embodiments of this invention, the hybrid keyboard further comprises a display device, especially a liquid crystal displaying device, to display input signals represented by the input keys having been stroke or actuated. The encoder used in the present invention may provide an organization function, to combine the particular signals generated by the stroke or actuated input keys and the particular motions detected by the motion sensor into a corresponding signal to be output (the “output signal.”) In another embodiment of this invention, the function of the encoder includes converting the “swinging” motion detected by the motion sensor into an instruction that represents the action of “output a signal” and the input key assembly further comprises a buffer memory, to store a predetermined number of the output signals. The output module outputs the output signals stored in the buffer memory in response to the “output a signal” instruction of the encoder.

In some embodiments of the present invention the combinations of the striking of the input keys and the detection of the motion sensor are defined to include the time sequence of the keystrokes and the motions as detected. In other embodiments, the defined combinations include the combination of the input keys as stroke and the detected motions that happens simultaneously.

In the application the output module may be a wired output module or a wireless output module. If it is a wired module, it may be connected to one or more main machine, so to operate or to control the main machine or machines. The connection of the output module and the main machine(s) may be a wire, a cable, a soft cable etc. The communication interface may be any conventional interface, such as the USB interface, the PCMCIA interface, the SATA interface, the PCI interface, or any non-standard communication interface. If it is a wireless module, it may exchange data with the main machine or machines via the infrared, microwave, radio or other wireless communication channels. In these embodiments, the output module may further include an interface controller, to convert the output signals into a desired format, and a transmitter to transmit the converted signals.

When using the invented hybrid keyboard, the user may strike or actuate the input keys and, in combination, wave or swing the hybrid keyboard, to generate the desired output signals. The user may also simply wave or swing the hybrid keyboard, to have the hybrid keyboard output the desired output signals.

These and other objectives and advantages of the present invention may be clearly understood from the detailed descriptions by referring to the following drawing.

### BRIEF DESCRIPTION OF THE DRAWING

FIG. 1 is the systematic diagram of the hybrid keyboard of the present invention.

### DETAILED DESCRIPTION OF THE INVENTION

The present invention provides a novel hybrid keyboard. The invented hybrid keyboard accepts the combination of 2 or more types of the key-input operations by the user, converts the combination into predetermined signals and transmits them to a main machine. Here, the key-input operations include the motions of the hybrid keyboard itself. The hybrid keyboard combines the key-striking operations and the motions of the hybrid keyboard and converts the combinations into control signals acceptable to the main machine. In the followings, the structure, system, operations and functions of the hybrid keyboard of the present invention will be described in details.

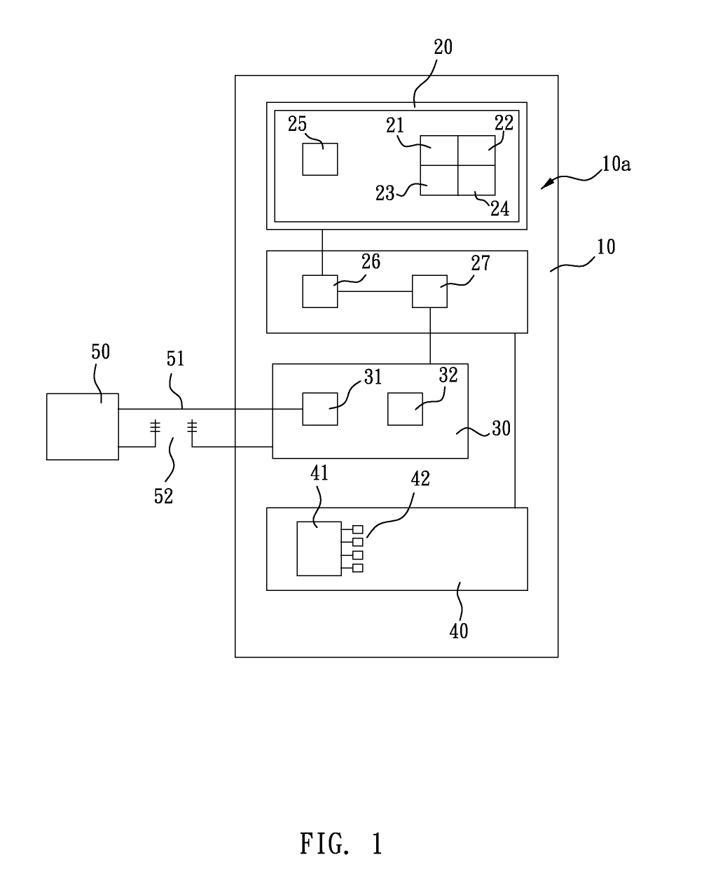

FIG. 1 is the systematic diagram of the hybrid keyboard of the present invention. As one may see from this figure, the hybrid keyboard of the present invention includes a main body 10, an input key assembly 20 and an output module 30. The main body 10 may be made from materials such plastic, metal, metal alloy, wood, paper, ceramic or other material or a composite material, has a particular shape and provides an accommodation space 10a. The input key assembly 20 includes at least one input key 21-24, at least one motion sensor 25 and an encoder 26. The input keys 21-24 may be any commercially available input key, such the mechanical input key, the capacitive input key or any other types of the input key. Input devices that have no striking keys, such as the joystick, may also be used in this invention. The motion sensor 25 may be any sensor that detects the motion or the displacement of an object. Applicable motion sensors include the accelerometer, the gyroscope etc. The input keys 21-24 and the motion sensor 25 are commercially available in the market, therefore detailed descriptions thereof are omitted. The encoder 26 is in connection with each of the input keys 21-24 and the motion sensor 25 and is provided a buffer memory 27. The input keys 21-24 as stroke and the motions as detected by the motion sensor 25 and their time sequence are stored in the buffer memory 27. A predetermined output signal is generated, when the combination of the input keys as stroke, the motions as detected and their time sequence matches a defined combination.

The quantity of the input keys and their quantity are not limited to any number. In general, it is preferable to have as less input keys as practicable in a hybrid keyboard, as long as the user is not required to strike too many times the input keys to input a particular signal. In application it is preferable to include several numeric keys in the input keys. It is even possible to include all the 10 numeric keys 0-9 in the input keys. However, in other applications it is not necessary to include a numeric key. In some applications, certain character keys, such as those of the Roman alphabetic letters, while in other applications the input keys include only symbols keys. In most cases the input keys include the combination of the numeric keys, the character keys and the symbol keys. As to the number, the combination and the arrangements of the input keys, there are no particular technical requirements; all depend on the convenience in applications and the requirements in fabrication.

The output module 30 is in connection with the input key assembly 20 and both are provided in the accommodation space 10a of the main body 10. Of course, it is possible and allowable to expose all or a part of the output module 30 and/or the input key assembly 20 from the accommodation space 10a of the main body 10. The output module 30 includes a transmitter 31, to pick up the signals generated by the input key assembly 20 and temporarily stored in the buffer memory 27 and send out the picked up signals, when the output module 30 receives the “output a signal” instruction of the input key assemble 20. The output module 30 may further include an interface controller 32, to convert the output signals into a particular required format, to facilitate the transmission of the output signals through the applicable communication channels or interfaces.

The output module 30 may be a wired output module or a wireless output module. In the case of a wired module, it may be connected to one or more main machines, to operate or to control the main machine or machines. The connection of the output module and the main machine(s) may be made by a wire, a cable, a soft cable etc. The communication interface may be any conventional interface, such as the USB interface, the PCMCIA interface, the SATA interface, the PCI interface, or any non-standard communication interface. If it is a wireless module, it may exchange data with the main machine or machines via the infrared, microwave, radio or other wireless communication channels. The communication protocols used in the output module 30 may be any public, standard protocol or any non-public, non-standard protocol. The structure, functions and operations of the transmitter 31 and the interface controller 32 and their communication interfaces or communication protocols may be realized by referring to the components, technology or documents relating to the commercially available products. Detailed descriptions thereof are thus omitted.

The hybrid keyboard of this invention may further include a display device 40, in connection with the input key assembly 20. The display device 40 may be any known displaying device, such as the liquid crystal displaying device, and used in the present invention. The display device 40 generally includes a displaying screen 41 and a controller 42. The display device 40 displays the keys as stroke or actuated and the signals represented by the motions as detected. The display screen 41 may be provided in the surface of the main body 10, to function as the shelter of the main body 10 or to form a part of the main body 10. The display device 40, however, is not a necessary component of this invention. In most cases the displaying function is not required.

The encoder 26 of the present invention provides one or more combination functions, to combine the striking operations of the input keys 21-24 and the motions detected by the motion sensor 25 and to convert the particular combinations into their corresponding output signals. In one embodiment of this invention the functions of the encoder 26 include to convert the swinging motion of the hybrid keyboard, as detected by the motion sensor 25, into an instruction of “output a signal.” This instruction actuates the output module 30 to output the output signals stored in the buffer memory 27.

When using the invented hybrid keyboard, the user may strike or actuate the input keys and, in combination, wave or swing the hybrid keyboard, to generate the desired output signals. The user may also simply wave or swing the hybrid keyboard, to have the hybrid keyboard output the desired output signals.

In the followings, certain examples will be given to describe the operation of the invented hybrid keyboard. Several examples showing how the encoder 26 interprets the combinations of the striking operations of the input keys and the motions detected by the motion sensor are in particular given as illustrations.

### Exemplary Application I:

Using the swinging motion detected by the motion sensor 25 as an “output a signal” instruction.

In this example, the encoder interprets the swinging motion of the hybrid keyboard, operated by the user and detected by the motion sensor 25, as an “output a signal” instruction. The encoder 25 thus provides the instruction directly to the output module 30. Upon the receipt of such an instruction, the output module 30 picks up the signals temporarily stored in the buffer memory 27 and sends out the signals using the transmitter 31, after the signals have been converted into a predetermined format by the interface controller 32. The signals travel through the wired channel 51 or the wireless channel 52 and reach the main machine 50, to initialize desired operations or control functions.

In this example, the user may first strike the input keys 21-24 to input a group of codes, such 0123, and store the codes in the buffer memory 27 as the output signals. The user then swing the main body 10 of the hybrid keyboard to transmit the output signals to the main machine.

### Exemplary Application II:

Using the combination of the shaking motions detected by the motion sensor 25 and the striking operations of the input keys 21-24 as a group of codes.

In this example, the encoder 26 interprets the shaking motion of the hybrid keyboard, operated by the user and detected by the motion sensor 25, as a keystroke. For instance, in case numbers and characters/letters are represented by the same input keys in common, the shaking motion of the hybrid keyboard may be interpreted as a “switching” instruction between the “numeric key” function and the “character/letter key” function. As a result, the required number of the input keys may be reduced.

One example for the applications of such a design is in the case where the input keys 21-24 are initially set to the “numeric key” mode. In this mode, the user strikes the input keys 21-24 to generate signals representing numbers. The user then shakes the hybrid keyboard to switch into the “character/letter” mode. When the user strikes the input keys 21-24 thereafter, the encoder 25 interprets the keystroke as signals representing characters/letters. If the user shakes the hybrid keyboard again, the encoder switches the input keys 21-24 into the “numeric key” mode again. The keystrokes detected thereafter are thus interpreted as signals representing numbers. As a result, switching between the numeric mode and the character/letter mode may be realized without the need of an additional switching key.

### Exemplary Application III:

Using the various kinds of motions detected by the motion sensor 25 as keystrokes.

In this example, the encoder 26 interprets the various kinds of motions of the hybrid keyboard, operated by the user and detected by the motion sensor 25, as keystrokes. For instance, the swing motion of the hybrid keyboard to a particular direction is interpreted as the instruction to turn up the volume of a speaker, while swinging the hybrid keyboard to the opposite direction represents the instruction to turn down its volume.

In such an example, when the swinging motion detected reaches a predetermined quantity, such as when the swinging radius reaches a certain amount or when the swinging motion continues for a certain period of time, the encoder 26 generates the “output a signal” instruction. Upon receipt of such an instruction the output module 30 picks up the “turn up” or “turn down” instructions, or even the signals representing the changing magnitude of the volume, from the buffer memory 27, the interface controller 32 converts these signals/instructions into a desired format and the transmitter 31 sends out these signals/instructions. The signals and/or instructions are then transmitted to the main machine 50 through the wired communication channel 51 or the wireless communication channel 52, to turn up or down the volume of the speaker of the main machine.

Under such a design, when used as the remote controller of a TV, stereo or audiovisual player, the hybrid keyboard needs only a power key as its sole input key. This is because not only the volume but also the channels and the sections of a program to be played or replayed may be controlled by swinging or shaking the hybrid keyboard.

### Exemplary Application IV:

Using the motions of the hybrid keyboard in combination with simultaneous keystrokes as control signals.

In the preceding examples, the combinations of the keystrokes and the motions of the hybrid keyboard include their sequence in the time domain. In this example, the combinations include the keystrokes and the motions detected at the same time.

For instance, when the user strikes an input key or a plurality of the input keys, and simultaneously swings the hybrid keyboard, the encoder 26 interprets the swinging motion as the “output a signal” instruction and sends the instruction to the output module 30. Upon the “output a signal” instruction, the output module 30 picks up the output signals, represented by the input key as stroke or the group of input keys as stroke and temporarily stored in the buffer memory, the interface controller 32 converts the output signals into a desired format and the transmitter 31 sends out the output signals.

In addition to the above examples, those skilled in the art may easily realize or derive other applications, controls or their combinations by using the invented hybrid keyboard. These and other variations, modifications and applications are all within the scope of this invention. Details thereof are thus omitted.

In the descriptions above, the terms “swinging,” “shaking” or “waving” are all in the natural language. The definitions and detection of these motions may be realized by quantifying the orientations of the motion sensor, the directions, the speed, the length, radius, angle or other features of the motions as detected and their variations, and the combinations of these factors, using the know art. These are well known to those skilled in the art and detailed descriptions thereof are thus omitted.

As described above, the present invention has presented a novel keyboard and its operation and mechanism. The invented hybrid keyboard provides, inter alia, the advantages of reducing the number of the input keys and enhancing the functionality of the keyboard.

As the present invention has been shown and described with reference to preferred embodiments thereof, those skilled in the art will recognize that the above and other changes may be made therein without departing from the spirit and scope of the invention.

What is claimed is:

1. A hybrid keyboard, comprising:
a main body, to provide an enclosing space;
an input key assembly including at least one input key and a corresponding encoder, to generate predetermined signals in response to striking operations of said at least one input key; and
an output module, to pick up said signals generated by said input key assembly and to output said signals;
characterized in that said input key assembly further comprises a motion sensor, to generate predetermined signals in response to motions detected by said motion sensor.

2. The hybrid keyboard according to claim 1, further comprising a display device, especially a liquid crystal display device, to display signals represented by the input keys having been stroke or actuated.

3. The hybrid keyboard according to claim 2, wherein the display device is a liquid crystal displaying device.

4. The hybrid keyboard according to claim 1, wherein said encoder provides a function to combine particular striking operations of said input key and particular motions detected by said motion sensor into corresponding signals.

5. The hybrid keyboard according to claim 4, wherein said combination of said particular striking operations and said particular motions further includes sequence of said particular striking operations and said particular motions.

6. The hybrid keyboard according to claim 4, wherein said combination of said particular striking operations and said particular motions comprises striking operations and motions detected simultaneously.

7. The hybrid keyboard according to claim 1, wherein said encoder converts a “swinging” motion detected by said motion sensor into an instruction that represents the action of “output a signal.”

8. The hybrid keyboard according to claim 1, further comprising a buffer memory to store a predetermined number of signals generated by said input key assembly.

9. The hybrid keyboard according to claim 1, wherein said output module is a wired module.

10. The hybrid keyboard according to claim 1, wherein said output module is a wireless module.

11. The hybrid keyboard according to claim 1, wherein said output module further comprises an interface controller, to convert signals generated by said input key assembly into a desired format, and a transmitter, to transmit said converted signals.
